(19) United States
(12) Patent Application Publication
(10) Pub. No.: US 2007/0257691 A1
(43) Pub. Date: Nov. 8, 2007

(54) Electrical connector assembly

(75) Inventor: Genn-Sheng Lee, Tu-Cheng (TW)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 11/799,719

(22) Filed: May 1, 2007

(30) Foreign Application Priority Data
May 2, 2006 (TW) 95115546

(51) Int. Cl. G01R 31/02

(52) U.S. Cl. 324/761

(57) ABSTRACT

An electrical connector assembly includes a socket (10), spring contacts on the socket, a supporting circuit plate (12), a plurality of capacitor components (13) on the supporting circuit plate, and an integrated circuit package (2) having power delivery lands. The spring contacts includes certain power delivery spring contacts (11) for engagement with corresponding power delivery lands on the package. The socket defines a region for the supporting circuit plate to be retained thereon. The plurality of capacitor components is arranged adjacent the respective power delivery spring contacts, and electrically connected with the capacitor components by the use of the supporting circuit plate. Since the capacitor components are directly incorporated into the socket, the conductive path between a voltage regulation module and the microprocessor package is minimized, thereby minimizing the inductance associated therewith.

### BACKGROUND OF THE INVENTION

1. Field of the Invention

The present invention relates to the art of electrical connectors, and more particularly to an electrical connector assembly integrated with passive components, such as capacitors.

2. The General Background

In a power delivery system, varying computing demands of the microprocessor (i.e. CPU) requires varying current demands from a power supply. The computing demands vary because of high clock speed circuits and power conservation design techniques, such as clock gating and sleep modes. These techniques result in fast, unpredictable and large magnitude changes in supply current ultimately requiring hundreds of amps within a few nanoseconds. The resulting current surge demanded by the microprocessor from a voltage regulator can cause unacceptable voltage spikes on the power delivery voltage according to the formula (dV=IR+Ldi/dt).

Attempts have been made to manage surge currents by placing decoupling capacitors throughout the power delivery system such as on a voltage regulation module, a circuit board, and the microprocessor package. Decoupling capacitors are typically located on the circuit board outside the microprocessor package, typically using several discrete decoupling capacitors mounted next to an electrical connector, which is often used to receive the microprocessor package, on the circuit board. In this approach, conductive traces on the circuit board connect the decoupling capacitors to power and ground connecting points, such as pins or lands, of the microprocessor.

The higher the frequency of operation of the microprocessor, the higher the resistance of the system due to the inductance, and higher resistance causes a higher voltage drop. Therefore, it is desirable to locate the decoupling capacitors as close to the microprocessor package or the electrical connector as possible in order to minimize the conductive path to minimize the inductance.

### SUMMARY OF THE INVENTION

An electrical connector assembly according to an embodiment of the present invention includes a socket, spring contacts on the socket, a supporting circuit plate, a plurality of capacitor components on the supporting circuit plate, and an integrated circuit package having power delivery lands. The spring contacts includes certain power delivery spring contacts for engagement with corresponding power delivery lands on the package. The socket defines a region for the supporting circuit plate to be retained thereon. The plurality of capacitor components is disposed adjacent the respective power delivery spring contacts, and electrically connected with the capacitor components by the use of the supporting circuit plate. As compared with the prior art, since the capacitor components are directly incorporated into the socket, the conductive path between a voltage regulation module and the microprocessor package is minimized, thereby minimizing the inductance associated therewith.

Other features and advantages of the present invention will become more apparent to those skilled in the art upon examination of the following drawings and detailed description of preferred embodiments, in which:

### BRIEF DESCRIPTION OF THE DRAWINGS

FIG. 1 is an exploded, perspective view of an electrical connector assembly according to a first embodiment of the present invention;

FIG. 2 is a sketch view showing a first configuration of a spring contact, a capacitor component and a supporting circuit plate at an enlarged part A of the electrical connector assembly of FIG. 1;

FIG. 3 is a sketch view showing a second configuration of the spring contact, the capacitor component and the supporting circuit plate at the enlarged part A of the electrical connector assembly of FIG. 1;

FIG. 4 is a sketch view showing a third configuration of the spring contact, the capacitor component and the supporting circuit plate at the enlarged part A of the electrical connector assembly of FIG. 1;

FIG. 5 is a sketch view showing a fourth configuration of the spring contact, the capacitor component and the supporting circuit plate at the enlarged part A of the electrical connector assembly of FIG. 1;

FIG. 6 is an exploded, perspective view of an electrical connector assembly according to a second embodiment of the present invention, but not showing a supporting circuit plate and a capacitor component thereon; and

FIG. 7 is a plan view showing the supporting circuit plate and the capacitor component on the supporting circuit plate of the electrical connector assembly of FIG. 6.

### DETAILED DESCRIPTION OF PREFERRED EMBODIMENT

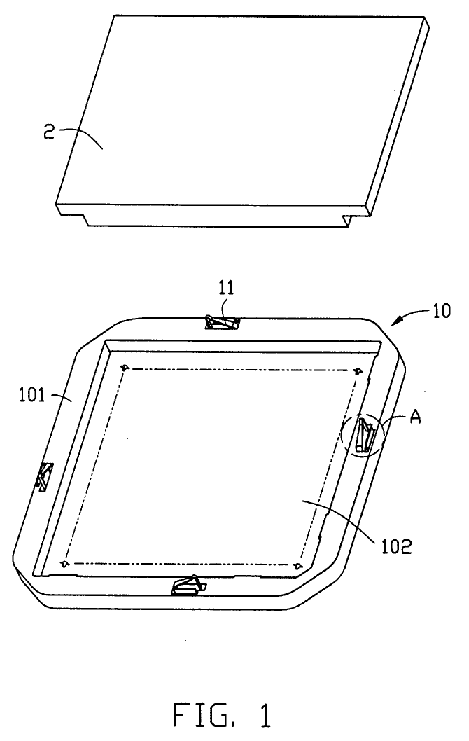

Referring to FIG. 1, an electrical connector assembly according to the first embodiment of the present invention includes a substantially rectangular socket body 10 with peripheral raised walls 101 surrounded to form a central cavity 102 for receiving an integrated circuit package 2, a plurality of spring contacts including a first set of spring contacts 11 retained onto the peripheral raised walls 101 and a second set of spring contacts (not shown) resided within the central cavity 102 of the socket body 10, and the integrated circuit package 2, such as an IC package, accommodated within the central cavity 102 of the socket body 10. The integrated circuit package 2 has on a bottom surface thereof a plurality of lands (not shown, as known in the prior art) that may include a first set of lands, such as power delivery lands, corresponding to the first set of spring contacts, and a second set of lands, such as signal transmission lands, corresponding to the second set of spring contacts. Therefore, the first set of spring contacts 11 is adapted for engaging with the first set of power delivery lands, and the second set of spring contacts is for engagement with the second set of signal transmission lands.

In this embodiment, a supporting circuit plate 22, with at least one capacitor 13 integrated therewith, is included within one passageway 100 of the socket body 10, which is often defined for receiving at least one of the first set of spring contacts 11. However, the supporting circuit plate 22 may be integrated into any other suitable location of the socket body 10, such as into regions defined for receiving the second set of spring contacts or any predetermined area of the socket body by a suitable molding process.

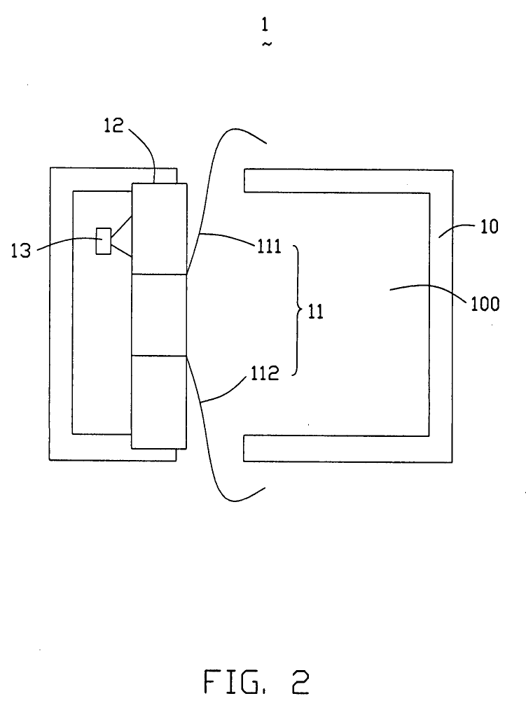

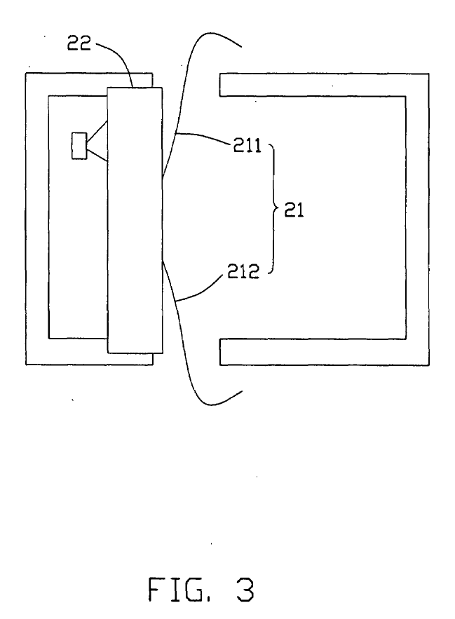

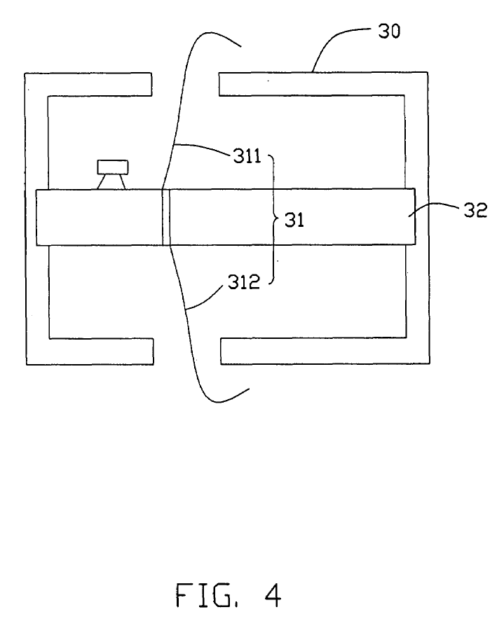

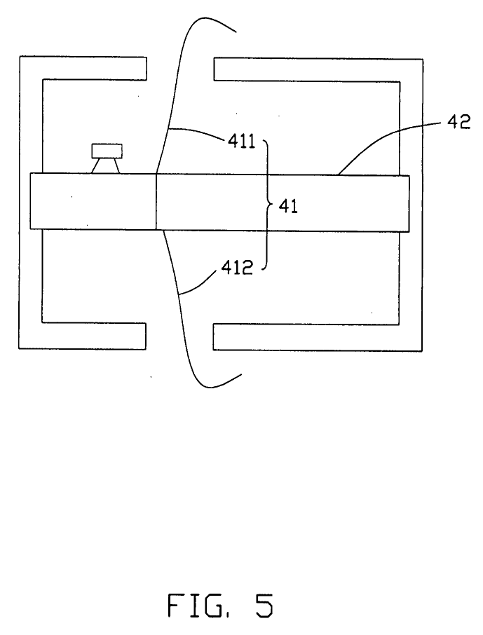

Referring to FIGS. 2 to 5, four specific configurations of the spring contact 11, the capacitor 13 and the supporting circuit plate 12 is shown to be interferingly retained in a common passageway 100 of the socket body 10. The common supporting circuit plate 12 electrically connects the spring contact 11 and the capacitor 13 with each other. As shown in FIG. 2, the supporting circuit plate 12 is vertically held with the passageway 100, and includes apertures for upper and lower spring contacts 111 and 112 to extend therethrough so as to secure the spring contacts 11 onto the supporting circuit plate 13. As shown in FIG. 3, the supporting circuit plate 13 is vertically held with the passageway. Upper and lower spring contacts 211 and 212 of a spring contact 21 are solderably secured onto the supporting circuit plate 22. As shown in FIG. 4, the supporting circuit plate 32 is horizontally held with the passageway, and includes apertures for upper and lower spring contacts 311 and 312 of a spring contact 31 to extend therethrough so as to secure the spring contact 31 onto the supporting circuit plate 32. As shown in FIG. 5, the supporting circuit plate 42 is horizontally held with the passageway. The supporting circuit plate 42 includes an aperture for the upper spring contact 411 of a spring contact 41 to extend therethrough to secure the upper spring contact 411 onto the supporting circuit plate 42, while the lower spring contact 412 is solderably secured onto the supporting circuit plate 42. However, in addition to the horizontal and vertical arrangements, the supporting circuit plate may have any other suitable arrangement, such as in tilting arrangements of varying angles with respect to a horizontal direction.

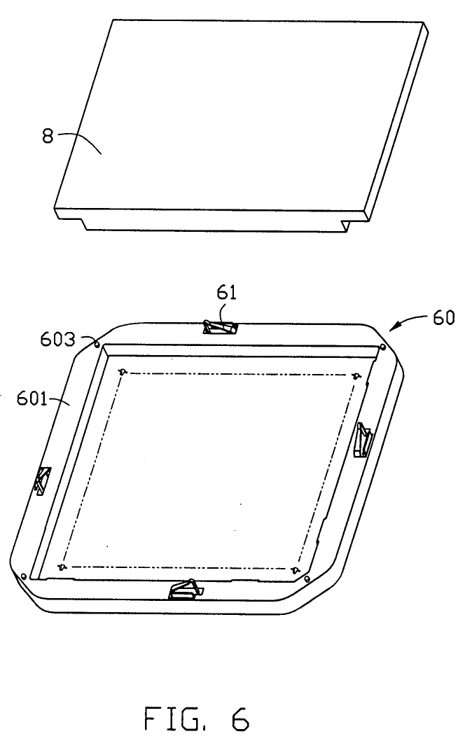

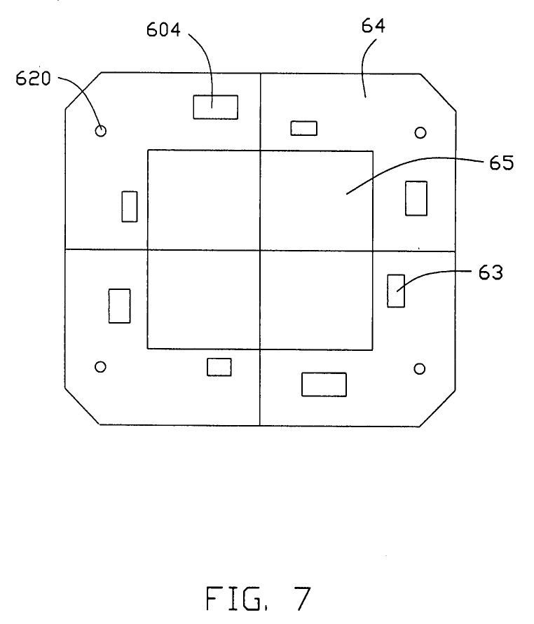

Referring to FIGS. 6 to 7, an electrical connector assembly according to the second embodiment of the present invention is shown. The electrical connector assembly is similar to that of the first embodiment, except for the location and configuration of the supporting circuit plate 62. The supporting circuit plate 62, with a plurality of capacitors 63 integrated therewith, is of a substantially rectangular shape in compliance with the shape of a socket body 60, and includes a peripheral side pieces 64 to be engaged on a surface region of raised walls 601 of the socket body 10. These side pieces 64 of the supporting circuit plate 62 includes a central hole 65 for the second set of spring contacts to be exposed out for engagement with signal transmission lands (not shown) of a integrated circuit package 8, and a plurality of side recesses 604 for the first set of spring contacts 61 to extend therethrough in order for electrical connection to corresponding power delivery lands (not shown) of the integrated circuit package 8, and several apertures 620 for receiving tabs 603 of the peripheral raised walls 601 so as to mount the supporting circuit plate 62 to the socket body 60. When the supporting circuit plate is assembled onto the socket body by engagement of the tabs 603 of the socket body 60 and the apertures 620 of the supporting circuit plate 62, the plurality of capacitor 63 is preferably proximate to the respective one of the first set of spring contacts 61, or predetermined one of the second set of spring contacts.

From the above embodiments, it can be seen that, since the capacitor or capacitors are directly incorporated into the socket body, the conductive path between a voltage regulation module and the microprocessor package is minimized, thereby minimizing the inductance associated therewith.

While the present invention has been described with reference to preferred embodiments, the description of the invention is illustrative and is not to be construed as limiting the invention. Various of modifications to the present invention can be made to preferred embodiments by those skilled in the art without departing from the true spirit and scope of the invention as defined by the appended claims.

What is claimed is:

1. An electrical connector assembly comprising:
a socket;
an integrated circuit package having lands;
spring contacts on said socket, said spring contacts engaged with lands on said package;
a supporting circuit plate, said socket defining a region for said supporting circuit plate to be retained thereon;
each spring contact disposed on the supporting circuit plate; and
at least one capacitor component on said supporting circuit plate and adjacent said spring contact, said at least one capacitor component being electrically connected with said spring contact by said supporting circuit plate.

2. The electrical connector assembly as recited in claim 1, wherein said socket includes a plurality of passageways, said supporting circuit plate with the spring contact and said at least one capacitor thereon interferingly held within one of the passageways.

3. The electrical connector assembly as recited in claim 2, wherein said supporting circuit plate is vertically held within the passageway.

4. The electrical connector assembly as recited in claim 3, wherein said supporting circuit plate includes an aperture, said spring contact extending through said aperture to be secured onto said supporting circuit plate.

5. The electrical connector assembly as recited in claim 3, wherein said spring contact is solderably secured onto said supporting circuit plate.

6. The electrical connector assembly as recited in claim 2, wherein said supporting circuit plate is horizontally held within the passageway.

7. The electrical connector assembly as recited in claim 6, wherein said supporting circuit plate includes an aperture, said spring contact extending through said aperture to be secured onto said supporting circuit plate.

8. The electrical connector assembly as recited in claim 6, wherein said spring contact is solderably secured onto said supporting circuit plate.

9. An electrical connector assembly comprising:
a socket;
an integrated circuit package having power delivery lands;
spring contacts on said socket, said spring contacts including certain power delivery spring contacts engaged with corresponding power delivery lands on said package;
a supporting circuit plate, said socket defining a region for said supporting circuit plate to be retained thereon; and
a plurality of capacitor components disposed on the supporting circuit plate and adjacent the respective power delivery spring contacts, the capacitor components electrically connecting with the capacitor components by said supporting circuit plate.

10. The electrical connector assembly as recited in claim 9, wherein said supporting circuit plate is engaged onto a mating surface of the socket, said supporting circuit plate including apertures for upper mating portions of the spring contacts to extend through, said capacitor components disposed on locations different than that of the apertures.

11. The electrical connector assembly as recited in claim 9, wherein said socket includes a plurality of passageways for receiving the respective spring contacts, said supporting circuit plate interferingly held within one of the passageways.

12. The electrical connector assembly as recited in claim 11, wherein said supporting circuit plate is vertically held within the passageway.

13. The electrical connector assembly as recited in claim 12, wherein said supporting circuit plate includes an aperture, said spring contact extending through said aperture to be secured onto said supporting circuit plate.

14. The electrical connector assembly as recited in claim 12, wherein said spring contact is solderably secured onto said supporting circuit plate.

15. The electrical connector assembly as recited in claim 11, wherein said supporting circuit plate is horizontally held within the passageway.

16. The electrical connector assembly as recited in claim 15, wherein said supporting circuit plate includes an aperture, said spring contact extending through said aperture to be secured onto said supporting circuit plate.

17. The electrical connector assembly as recited in claim 15, wherein said spring contact is solderably secured onto said supporting circuit plate.

18. An electrical connector assembly comprising:
a socket defining a center region and a periphery region;
an integrated circuit package located on the socket and having lands thereof;
at least one contact disposed in the periphery region and engaged with one of said lands on said package; and
at least one capacitor located in said periphery region and electrically connected with said contact.

19. The electrical connector assembly as claimed in claim 18, wherein both the capacitor and the at least one contact are electrically and mechanically connected to a supporting circuit plate which is retained in the periphery region.

20. The electrical connector assembly as claimed in claim 19, wherein said at least one contact defines a spring arm engaged with said one of the lands, and a soldering section soldered on a printed circuit board on which the socket is seated.
